(19) United States
(12) Patent Application Publication
(10) Pub. No.: US 2011/0017506 A1
(43) Pub. Date: Jan. 27, 2011

(54) MODULAR OVER-MOLD HARNESS

(76) Inventor: Selvin Kao, Rancho Santa Margarita, CA (US)

Correspondence Address: SHELDON MAK & ANDERSON PC, 100 Corson Street, Third Floor, PASADENA, CA, 91103-3842, US

(21) Appl. No.: 12/507,780

(22) Filed: Jul. 22, 2009

(51) Int. Cl. H01L 23/28; B29C 45/14

(52) U.S. Cl. 174/521; 425/116; 264/272.14

(57) ABSTRACT

An over-molded harness including a plurality of bundled flexible electric wires, an electrical or electronic element electrically connected between at least two of the wires, and at least a portion of the bundled electrical wires having an over-molded insulative covering, whereby the electrical or electronic element is unsupported by other than primarily by the over-molded insulative covering and secondarily by the flexible electric wires, the electrical or electronic element being both precisely located and completely enclosed within the insulative covering.

### BACKGROUND

The present invention relates to conductive wire harnesses, and more particularly such harness that include an over-molded element formed of a material such as a polymer.

In some applications such as powered hand tools, components such as motors, control circuits, external control elements (switches, etc.) and displays are variously distributed in the device and interconnected by various electrical wires that are often bundled as a wiring harness. Over-molding of such harnesses or portions thereof for preventing wire damage, for example is known. See, for example, U.S. Pat. No. 7,204,724 to Holtz, U.S. Pat. No. 7,393,218 to Pavlovic, and U.S. Pat. No. 7,462,780 to Marsh et al. A mold for over-molding a harness is disclosed in U.S. Pat. No. 6,071,446 to O'Brien et al.

In some situations, such as when a needed component does not fit well within the space of a connected component, or when a new component is needed within an existing product design, and particularly when the physical location of the needed component is critical, the known prior art does not provide a satisfactory solution.

Thus there is a need for an over-molded harness that includes one or more otherwise unsupported circuit elements such as inductors, varistors, and integrated circuits in the over-molding.

### SUMMARY

The present invention meets this need by providing an over-molded wire harness that includes at least one otherwise unsupported circuit element that is precisely located. In one aspect of the invention, an over-molded harness includes a bare harness including a plurality of bundled flexible electric wires and a circuit component having electrical connections between at least two of the wires; and at least a portion of the bare harness having an over-molded body forming an insulative covering, whereby the circuit component is unsupported by other than primarily by the over-molded insulative covering and secondarily by the flexible electric wires, the component being both precisely located and completely enclosed within the insulative covering. As used herein, “circuit component” includes an electrical component such as a resistor, a varistor, and an inductor, or an electronic element such as a diode, a transistor, and an integrated circuit. The circuit component can include a component body and electrical leads, the harness preferably further including a pre-mold body having the component body substantially encapsulated therein to form a pre-mold module with portions of the leads projecting from the pre-mold body, the pre-mold body having one or more registration surfaces for precisely locating the pre-mold module within the over-molded body. The one or more registration surfaces can include a parallel-spaced pair of registration openings.

The electric wires can have insulation coverings, the over-mold body preferably having locating cavities formed therein for facilitating positioning of the wires away from outside surfaces of the over-mold body, the bare harness further including lengths of insulative tubing located over the electrical connections and over portions of the wires to be adjacent the locating cavities, for providing double insulation layers between conductors of the wires and the outside surfaces of the over-mold body. The over-mold body can have a major cavity formed therein for receiving an external member in registration with the over-mold body, the circuit component preferably being precisely located proximate the major cavity and closely spaced inwardly from the outside surface of the over-mold body for sensing an operating parameter such as speed associated with the external member. The over-molded harness having the major cavity can be provided in an assembly with a motor having a major projection, the major projection engaging and registering the over-mold body. The major projection of the motor can be formed of an insulating material, the over-mold harness in the assembled condition preferably providing double insulation of the electrical wires and the circuit component within the over-mold body.

In another aspect of the invention, apparatus for making an over-molded harness having a plurality of flexible electrical wires and a circuit component to be precisely located within an over-molded body of the harness, wherein the circuit component has a component body and electrical leads, includes: a pre-mold die set including (a) a first die block formed for receiving a portion of at least one of the leads and having a first component registration surface for contacting the component body, the circuit component being precisely located relative to the first die block when the component body is seated contacting the component registration surface with the portion of the at least one lead received in the first die block; (b) a second die block configured for facing contact with the first die block, the first and second die blocks forming a pre-mold cavity for enclosing the component body and portions of the leads in a pre-mold body to form a pre-mold module having portions of the electrical leads projecting therefrom; and (c) means for defining at least one module registration surface within the cavity, the module registration surface being spaced from the circuit component when the circuit component is seated within the cavity. The apparatus also includes (d) an over-mold die having a main cavity for receiving the pre-mold module and portions of a plurality of bundled flexible electric wires, the projecting lead portions being electrically connected to respective ones of the wires; and (e) means for precisely registering the pre-mold module within the main cavity by contacting the at least one module registration surface, whereby, when the over-molded body is formed in the main cavity, the circuit component is both precisely located and completely enclosed within the over-molded body, the circuit component being unsupported by other than primarily by the over-molded insulative covering and secondarily by the flexible electric wires. The at least one module registration surface of the pre-mold module can include a parallel-spaced pair of registration openings, the means for precisely registering the pre-mold module including a spaced pair of registration pins projecting into the main cavity.

A further aspect of the invention provides an over-molding process for precisely locating a circuit component in an over-molded body of an electrical wire harness. The process includes the steps of: (a) providing a pre-mold module having a body of the circuit component substantially enclosed therein, with electrical leads of the component projecting from a molded body of the module, the molded body having one or more registration surfaces formed thereon; (b) providing an over-mold die having a main cavity for forming an over-mold body, and having one or more registration elements therein for engaging the one or more registration surfaces of the molded body of the pre-mold module; (c) providing a set of flexible electrical wires for the harness; (d) electrically connecting the leads of the circuit component to corresponding ones of the electrical wires; (e) bundling the wires to form a bare harness; (f) seating the pre-mold module in the over-mold die, in registered engagement with the one or more registration elements, portions of the bare harness extending within the main cavity of the over-mold die; feeding and setting an over-molding material into the over-mold die; and removing the completed over-molded harness from the over-mold die.

The step of providing the pre-mold module preferably includes the further steps of (a) providing a pre-mold die for receiving the circuit component, the pre-mold die having counterparts of the registration elements for forming the registration surfaces; (b) registering the circuit component in the pre-mold die; (c) feeding and setting a pre-molding material into the pre-mold die; and (d) removing the completed pre-mold module from the pre-mold die. The registration elements of the over-mold die can include a spaced pair of registration pins. Preferably the electrical wires have insulation coverings and the over-mold die has projections extending into the main cavity for positioning the wires away from outside surfaces of the main cavity, the method comprising the further step of locating insulative tubing over the electrical connections and over portions of the wires to be adjacent the projections, for providing double insulation layers between conductors of the wires and the outside surfaces of the over-mold body.

### DRAWINGS

These and other features, aspects, and advantages of the present invention will become better understood with reference to the following description, appended claims, and accompanying drawings, where:

FIG. 1 is a top plan view of an over-molded wire harness according to the present invention;

FIG. 2 is a detail plan view within region 2 of FIG. 1;

FIG. 3 is sectional detail view on line 3-3 in FIG. 2;

FIG. 4 is a sectional detail view on line 4-4 in FIG. 2;

FIG. 5 is a sectional detail view on line 5-5 in FIG. 2;

FIG. 6 is a detail plan view of a pre-mold circuit element module of the harness of FIG. 1;

FIG. 7 is a front elevational view of the pre-mold circuit element module of FIG. 6;

FIG. 8 is a side view of the pre-mold circuit element module of FIG. 6;

FIG. 9 is a fragmentary perspective view showing alignment of the over-molded wire harness of FIG. 1 with a device motor for assembly therewith;

FIG. 10 is a plan view of a molding tool portion for the over-molded harness of FIG. 1;

FIG. 11 is a sectional view on line 11-11 of FIG. 10;

FIG. 12 is a plan view of another molding tool portion for the over-molded harness of FIG. 1;

FIG. 13 is a perspective view of a die set for producing the pre-molded module of FIGS. 6, 7, and 8; and

FIG. 14 flow chart of a process for making the over-molded harness of FIG. 1.

### DESCRIPTION

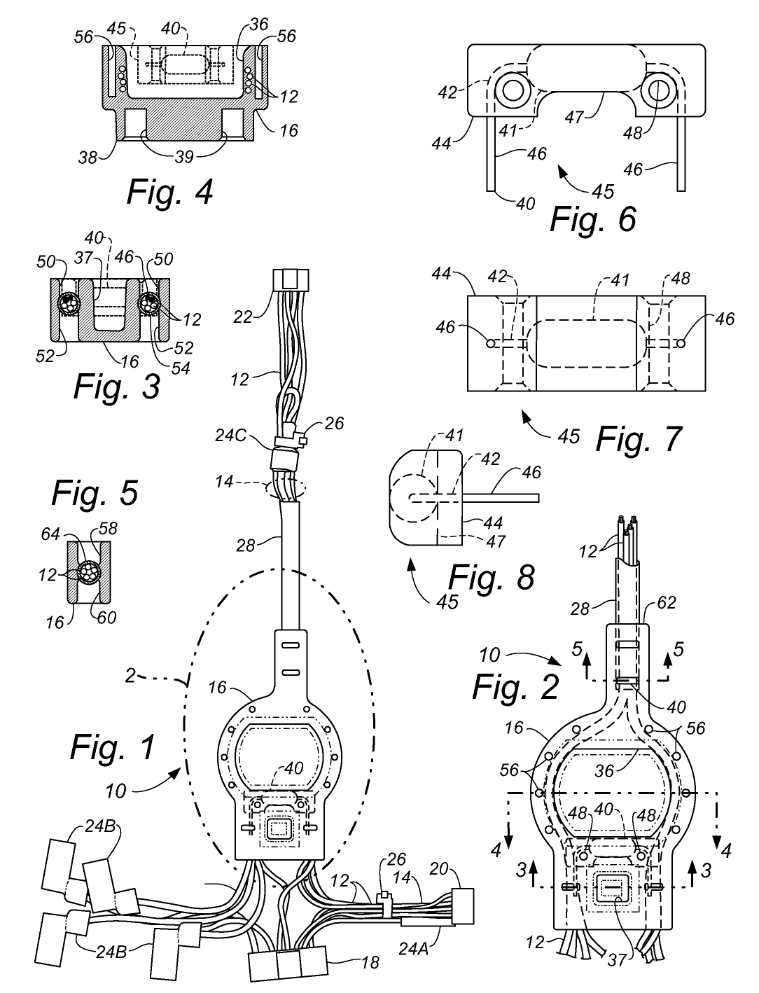

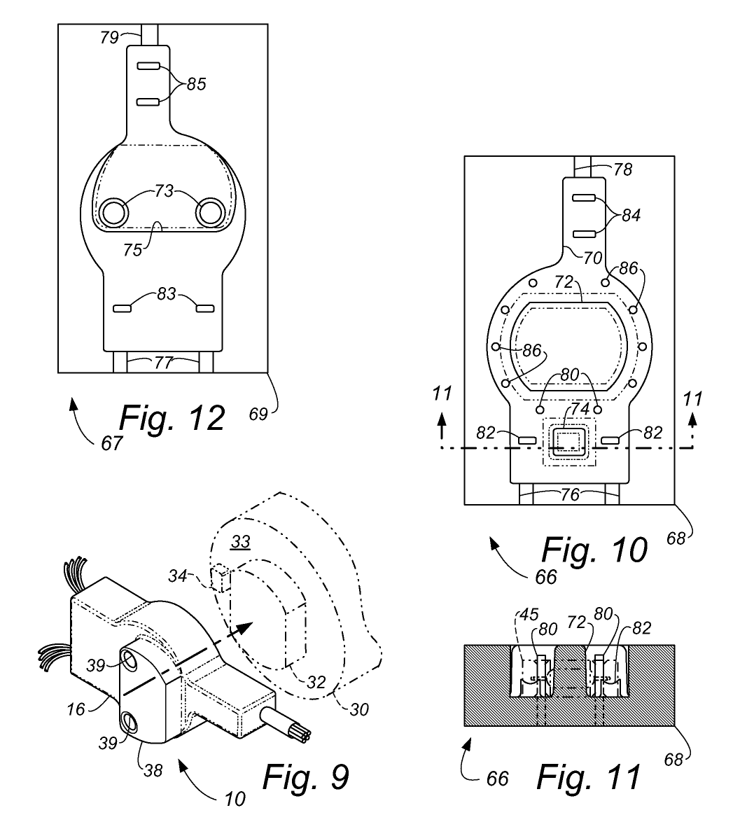

The present invention is directed to an over-molded wire harness that incorporates a precisely positioned circuit element that is supported only by the over-molding material and secondarily by flexible wires of the harness. With reference to FIGS. 1-9 of the drawings, an over-molded harness 10 includes a bundled plurality of electrical wires 12 forming a bare harness 14, and an over-molded body 16 that encloses and secures at least a portion of the bare harness. As further shown in FIG. 1, an exemplary configuration of the over-molded harness 10 is branched, with groups of the wires having various singular and ganged terminations; particularly a first connector 18 terminating eight of the wires 12, a second connector 20 terminating five of the wires, a third connector 22 also terminating five of the wires, and several variously configured singular and/or doubled terminations, designated terminators 24A, 24B, and 24C. Also, the bare harness 14 optionally includes one or more cable ties 26, and an insulating sleeve 28. It will be understood that the arrangement of wires and terminations of the bare harness 14 is to suit particular devices incorporating the over-molded harness 10, and forms no part of the present invention. As shown in FIG. 9, the over-molded body 16 is configured to register on the end of a device motor 30 having a major end projection 32 from an end face of the motor, and a minor end projection 34 from the face 33, the body 16 having correspondingly shaped a major cavity 36 and a minor cavity 37. A housing (not shown) of the device serves to retain the body 16 seated on the motor 30, the over-molded body 16 having a raised pad portion 38 that includes a pair of registration cavities 39 for engagement by the housing as also shown in FIG. 4.

According to the present invention, a circuit element in the form of an inductor 40 having an inductor body 41 and axial leads 42 is precisely positioned within the over-molded body 16 as described herein. With particular reference to FIGS. 6-8, the inductor 40 is encapsulated in a pre-mold body 44 to form a pre-mold module 45, the leads 42 having formed bends with portions 46 of the leads projecting in spaced parallel relation from the pre-mold body 44. The pre-mold body 44 has a narrowed portion 47 that serves to precisely confine the inductor body 41 in a direction parallel to the parallel projecting lead portions 45 of the leads 42. Further, the inductor body 41 is formed having a parallel-spaced pair of registration openings 48 that are oriented perpendicular to the inductor body and to the projecting lead portions 46.

As shown in FIG. 3, the over-molded body 16 is formed having a pair of first upper locating cavities 50 and a pair of first lower locating cavities 52 that are formed by respective posts (described below) for positioning particular ones of the electrical wires 12 adjacent the minor cavity 37 during molding of the body 16. As further shown in FIG. 3, each of the lead portions 46 of the inductor 40 are electrically connected to respective ones of the wires 12, a short length of heat-shrink tubing 54 being installed over groups of the wires and covering the electrical connections.

As further shown in FIGS. 2 and 4, the over-molded body 16 is formed having a plurality of locating openings 56 for confining electrical wires proximate the major cavity 36, away from outer surfaces of the body. This feature insures that the wires 12 have double insulation, the material of the body providing an additional layer of insulation to the native insulating covering of the wires themselves. It will be understood that the major projection 32 of the motor 30 is formed of an insulating material, so that exposure of wires at the major cavity 36 of the over-molded body 16, if any, would not compromise the double insulation properties of the body 16.

As shown in FIGS. 2 and 5, the over-molded body 16 has an additional pair of second upper locating cavities 58 and second lower locating cavities 60 that are spaced toward a distal extremity 62 of the body 16. The locating cavities 58 and 60 are formed by additional posts (described below) as for the first locating cavities 50 and 52 of FIG. 3. The electrical wires 12 exiting the over-molded body 16 at the distal extremity 62 are covered by an insulating sleeve 64 that can be formed by a length of heat-shrink tubing. The sleeve 64 extends within the body beyond the second locating cavities 58 and 60 for maintaining double insulation of the wires 12.

Suitable materials for the pre-mold body 44 and the over-molded body 16 include PVC, TPE, and other shock-absorbing thermoplastic polymers, preferably in an electrical insulation grade that provides a secondary insulation layer to the wires. As described herein the over-molded harness 10 is believed to be acceptable as a direct double-insulation device and method for Underwriters Laboratory (UL) certification, thus eliminating a need for an additional insulation layer such as a film or mechanical plastic layer over the harness.

With further reference to FIGS. 10-12, a pair of molding tool portions, designated upper tool portion 66 (FIGS. 10 and 11) and lower tool portion 67 (FIG. 12) for producing the over-molded harness of FIG. 1 includes an upper die block 68 having an upper main cavity 70 shaped to form an upper portion of the over-molded body 16, and a lower die block 69 having a main cavity 71 to form a lower portion of the body. (The upper die block 68 is shown inverted from the orientation of the body 16 as depicted in FIGS. 1-5.) In use, the lower tool portion 67 (for example) would be inverted and clamped onto the upper tool portion 66, the main cavities 70 and 71 forming a single cavity for defining the outside shape of the over-molded body 16. It will be understood that the tool portions 66 and 67 are shown in simplified form, with conventional features such as guides and runners being omitted in the drawings.

The upper die block 68 is formed with a first projection 72 and a second projection 74 in the main cavity 70 for forming the major cavity 36 and the minor cavity 37 of the body 16. The die block 68 is also formed with a pair of first channels 76 for receiving groups of the electrical wires of the bare harness 14, and a second channel 78 for receiving the insulating sleeve 64. A pair of register pins 80 are fixedly installed in the die block 68, projecting into the main cavity 70 for precisely locating the pre-mold module 45, the module 45 to be seated in contact with the bottom of the main cavity 70. Further, a pair of first upper locating posts 82 and second upper locating posts 84 project into the main cavity 70 for defining the first and second upper locating the cavities 50 and 52 of the body 16 (shown in FIGS. 3 and 5); moreover, a plurality of locating pins 86 also project into the cavity 70 for defining the locating openings 56 of the over-molded body 16 (shown in FIG. 4).

Similarly, the lower die block 69 is formed with a pair of register posts 73 projecting within a pad cavity 75 for forming the registration cavities 39 in the pad portion 38 of the over-molded body 16. The die block 69 is also formed with a raised pair of first channels 77 that align with the first channels of the upper die block 68 for receiving the groups of the electrical wires of the bare harness 14, and a raised second channel 79 for receiving the insulating sleeve 64 in cooperation with the second channel of the die block 68. The raised form of the first and channels 77 and 79 of the lower die block 69 cooperate with deepened corresponding channels 76 and 78 of the upper die block to effect exit of the electrical wires 12 in offset relation to facing surfaces of the upper and lower die blocks. A pair first lower locating posts 83 and second lower locating posts 85 project into the main cavity 71 for defining the first and second lower locating cavities 52 and 60 of the body 16 (shown in FIGS. 3 and 5).

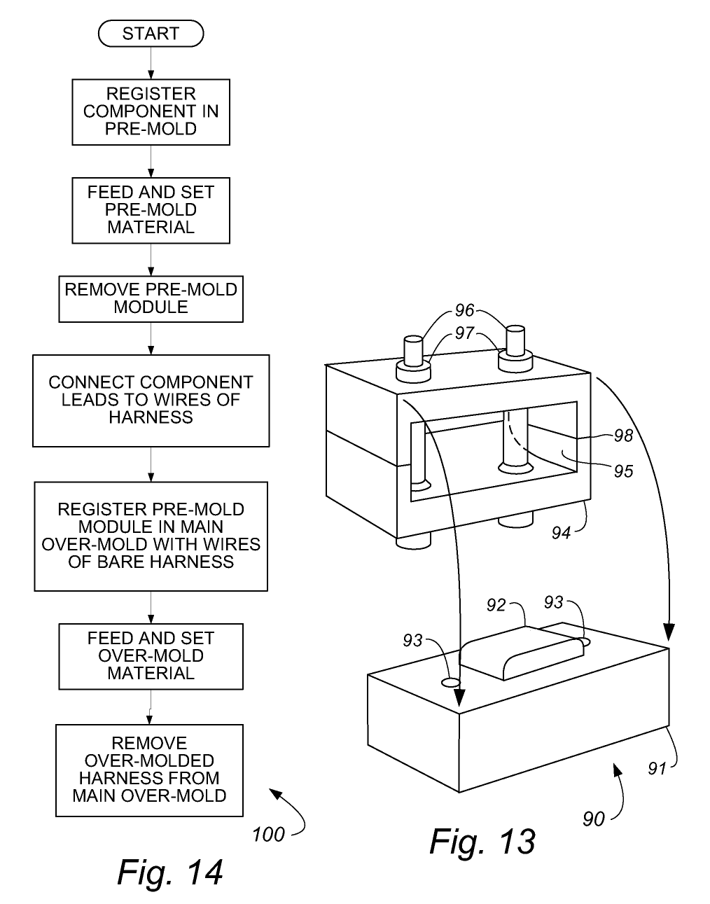

With further reference to FIG. 13 an exemplary die set 90 (shown in simplified form) for producing the pre-mold module 45 includes a first die block 91 having a raised portion 92 for forming the narrowed portion 47 of the pre-mold body 44, and spaced pair of lead holes 93 for receiving the lead portions 46 of the inductor 40 that are to be exposed. A mating second die block 94 has a pre-mold cavity 95 formed therein for forming the remainder of the pre-mold body 44, and a pair of registration pins 96 extending in parallel relation through the cavity 95. The registration pins 96 have tapered portions for forming countersink depressions at one end of each registration opening 48 of the pre-mold body (see FIGS. 6 and 7), and are stepped for receiving respective correspondingly shaped collars 97 that form opposite countersink depressions at opposite ends of the openings 48. The second die block 94 can also be split as indicated at 98 in FIG. 13. It will be understood that with the leads 42 of the inductor formed in predetermined coplanar relation to each other, the location of the inductor body 41 assumes a precise location relative to the first die block 91 when the body 41 rests on the raised portion 92. The pre-mold cavity 95 is preferably formed in close proximity to the inductor body 41 such that, when the pre-mold module 45 is seated in the upper die block 68, the inductor body 41 becomes precisely positioned proximate the major projection 32 and to the main portion of the motor 30 when the over-molded harness 10 is assembled therewith for accurate speed sensing of the motor.

With further reference to FIG. 14, an over-molding process 100 for precisely locating a circuit component in an over-molded body includes the steps of:

(a) providing a pre-mold module having a body of the circuit component substantially enclosed therein, with electrical leads of the component projecting from a molded body of the module, the molded body having one or more registration surfaces formed thereon;

(b) providing an over-mold die having a main cavity for forming an over-molded body, and having one or more registration elements therein for engaging the one or more registration surfaces of the molded body of the pre-mold module;

(c) providing a set of flexible electrical wires for the harness;

(d) electrically connecting the leads of the circuit component to corresponding ones of the electrical wires;

(e) bundling the wires to form a bare harness;

(f) seating the pre-mold module in the over-mold die, in registered engagement with the one or more registration elements, portions of the bare harness extending within the main cavity of the over-mold die;

(g) feeding and setting an over-molding material into the over-mold die; and

(h) removing the over-molded harness from the over-mold die.

The registration elements of the over-mold die can include the spaced pair of registration pins. The electrical wires preferably have insulation coverings and the over-mold die preferably has projections extending into the main cavity for positioning the wires away from outside surfaces of the main cavity, the method including the further step of locating insulative tubing over the electrical connections and over portions of the wires to be adjacent the projections, for providing double insulation layers between conductors of the wires and the outside surfaces of the over-molded body.

Although the present invention has been described in considerable detail with reference to certain preferred versions thereof, other versions are possible. Therefore, the spirit and scope of the appended claims should not necessarily be limited to the description of the preferred versions contained herein.

What is claimed is:

1. An over-molded harness comprising:
(a) a bare harness comprising:
(i) a plurality of bundled flexible electric wires; and
(ii) a circuit component having electrical connections between at least two of the wires; and
(b) at least a portion of the bare harness having an over-molded body forming an insulative covering, whereby the circuit component is unsupported by other than primarily by the over-molded insulative covering and secondarily by the flexible electric wires, the component being both precisely located and completely enclosed within the insulative covering.

2. The over-molded harness of claim 1, wherein the circuit component comprises a component body and electrical leads, the harness further comprising a pre-mold body having the component body substantially encapsulated therein to form a pre-mold module with portions of the leads projecting from the pre-mold body, the pre-mold body having one or more registration surfaces for precisely locating the pre-mold module within the over-molded body.

3. The over-molded harness of claim 2, wherein the one or more registration surfaces comprise a parallel-spaced pair of registration openings.

4. The over-molded harness of claim 1, wherein the electric wires have insulation coverings and the over-mold body has locating cavities formed therein for facilitating positioning of the wires away from outside surfaces of the over-mold body, the bare harness further comprising lengths of insulative tubing located over the electrical connections and over portions of the wires to be adjacent the locating cavities, for providing double insulation layers between conductors of the wires and the outside surfaces of the over-mold body.

5. The over-molded harness of claim 4, wherein the over-mold body has a major cavity formed therein for receiving an external member in registration with the over-mold body, the circuit component being precisely located proximate the major cavity and closely spaced inwardly from the outside surface of the over-mold body.

6. An assembly comprising:
(a) the over-molded harness of claim 5; and
(b) a motor having a major projection, the major projection engaging and registering the over-mold body.

7. The assembly of claim 6, wherein the major projection of the motor is formed of an insulating material, the over-mold harness in the assembled condition providing double insulation of the electrical wires and the circuit component within the over-mold body.

8. Apparatus for making an over-molded harness including a plurality of flexible electrical wires and a circuit component to be precisely located within an over-molded body of the harness, the circuit component having a component body and electrical leads, the apparatus comprising:
(a) a pre-mold die set comprising:
(i) a first die block formed for receiving a portion of at least one of the leads and having a first component registration surface for contacting the component body, the circuit component being precisely located relative to the first die block when the component body is seated contacting the component registration surface with the portion of the at least one lead received in the first die block;
(ii) a second die block configured for facing contact with the first die block, the first and second die blocks forming a pre-mold cavity for enclosing the component body and portions of the leads in a pre-mold body to form a pre-mold module having portions of the electrical leads projecting therefrom; and
(iii) means for defining at least one module registration surface within the cavity, the module registration surface being spaced from the circuit component when the circuit component is seated within the cavity;
(b) an over-mold die having a main cavity for receiving the pre-mold module and portions of a plurality of bundled flexible electric wires, the projecting lead portions being electrically connected to respective ones of the wires; and
(c) means for precisely registering the pre-mold module within the main cavity by contacting the at least one module registration surface,
whereby, when the over-molded body is formed in the main cavity, the circuit component is both precisely located and completely enclosed within the over-molded body, the circuit component being unsupported by other than primarily by the over-molded insulative covering and secondarily by the flexible electric wires.

9. The apparatus of claim 8, wherein the at least one module registration surface of the pre-mold module comprises a parallel-spaced pair of registration openings, and the means for precisely registering the pre-mold module comprises a spaced pair of registration pins projecting into the main cavity.

10. An over-molding process for precisely locating a circuit component in an over-molded body of an electrical wire harness, the process comprising the steps of:
(a) providing a pre-mold module having a body of the circuit component substantially enclosed therein, with electrical leads of the component projecting from a molded body of the module, the molded body having one or more registration surfaces formed thereon;
(b) providing an over-mold die having a main cavity for forming an over-mold body, and having one or more registration elements therein for engaging the one or more registration surfaces of the molded body of the pre-mold module;
(c) providing a set of flexible electrical wires for the harness;
(d) electrically connecting the leads of the circuit component to corresponding ones of the electrical wires;
(e) bundling the wires to form a bare harness;
(f) seating the pre-mold module in the over-mold die, in registered engagement with the one or more registration elements, portions of the bare harness extending within the main cavity of the over-mold die;
(g) feeding and setting an over-molding material into the over-mold die; and
(h) removing the over-molded harness from the over-mold die.

11. The process of claim 10, wherein the step of providing the pre-mold module comprises the further steps of providing a pre-mold die for receiving the circuit component, the pre-mold die having counterparts of the registration elements for forming the registration surfaces; registering the circuit component in the pre-mold die; feeding and setting a pre-molding material into the pre-mold die; and removing the pre-mold module from the pre-mold die.

12. The process of claim 10, wherein the registration elements of the over-mold die comprise a spaced pair of registration pins.

13. The process of claim 10, wherein the electrical wires have insulation coverings and the over-mold die has projections extending into the main cavity for positioning the wires away from outside surfaces of the main cavity, the method comprising the further step of locating insulative tubing over the electrical connections and over portions of the wires to be adjacent the projections, for providing double insulation layers between conductors of the wires and the outside surfaces of the over-mold body.
